(19) United States
(12) Patent Application Publication
(10) Pub. No.: US 2010/0164648 A1
(43) Pub. Date: Jul. 1, 2010

(54) INNOVATIVE CALIBRATION CIRCUIT AND METHOD FOR HIGH-FREQUENCY ACTIVE FILTERS

(76) Inventors: Lior Kravitz, Kfar Bilu (IL); Ze'ev Be'er, Tel Aviv (IL)

Correspondence Address: CARRIE A. BOONE, P.C.;c/o CPA Global, P.O. Box 52050, Minneapolis, MN, 55402, US

(21) Appl. No.: 12/345,429

(22) Filed: Dec. 29, 2008

(51) Int. Cl. H03H 7/12

(52) U.S. Cl. 333/165

(57) ABSTRACT

An enhanced quality band-pass filter is disclosed. The filter includes a Q-enhancement core for improving the quality of the filter performance. The system also includes a calibration circuit that monitors the oscillation of the Q-enhancement core and makes adjustments to the Q-enhancement core setting until the filter is not oscillating. By coupling the Q-enhancement core with a robust calibration scheme, the disclosed system maintains a higher quality filter.

### TECHNICAL FIELD

This application relates to calibration circuits and, more particularly, to a calibration circuit embedded within a Q-enhanced filter.

### BACKGROUND

Recent advances in both silicon technology and communications systems have led to greater integration levels in radio frequency integrated circuit (RFIC) systems, including support for multiple transceivers on the same chip, multiple frequency bands, and communication protocols. The requirements for concurrent operation and for co-existence due to integration pose strong filtering requirements on both the receiver (protecting itself from noise ingress) and the transmitter (preventing interference harmful to other systems and meeting more stringent regulatory requirements).

Traditionally, filtering is achieved using ceramic or surface acoustic wave (SAW) filters. Since the performance of on-chip filters is not sufficient, these ceramic or SAW filters are integrated off-chip. Q-enhanced filters have been the subject of research for many years, but only recently have found their way into actual product designs. This type of active filter is notorious for its ability to oscillate in certain conditions, if not controlled with a high degree of precision. The risk of uncontrolled oscillation prevents the integration of such active filters in actual mass-production designs. By designing the Q-enhanced filters very conservatively, oscillations are avoided, but much of the possible gain from Q-enhancement is negated.

Thus, there is a continuing need for a Q-enhanced filter that overcomes the shortcomings of the prior art.

### BRIEF DESCRIPTION OF THE DRAWINGS

The foregoing aspects and many of the attendant advantages of this document will become more readily appreciated as the same becomes better understood by reference to the following detailed description, when taken in conjunction with the accompanying drawings, wherein like reference numerals refer to like parts throughout the various views, unless otherwise specified.

FIGS. 1 and 2 are schematic block diagrams of an enhanced filtering system, according to some embodiments; and

FIGS. 3 and 4 are flow diagrams showing the enhanced filtering operations performed by the filtering systems of FIGS. 1 and 2, according to some embodiments.

### DETAILED DESCRIPTION

In accordance with the embodiments described herein, an enhanced quality band-pass filter system is disclosed. The filter includes a Q-enhancement core for improving the quality of the filter performance. The system also includes a calibration circuit that monitors the oscillation of the Q-enhancement core and makes adjustments to the Q-enhancement core setting until the filter is not oscillating. By coupling the Q-enhancement core with a robust calibration scheme, the disclosed system maintains a higher quality filter.

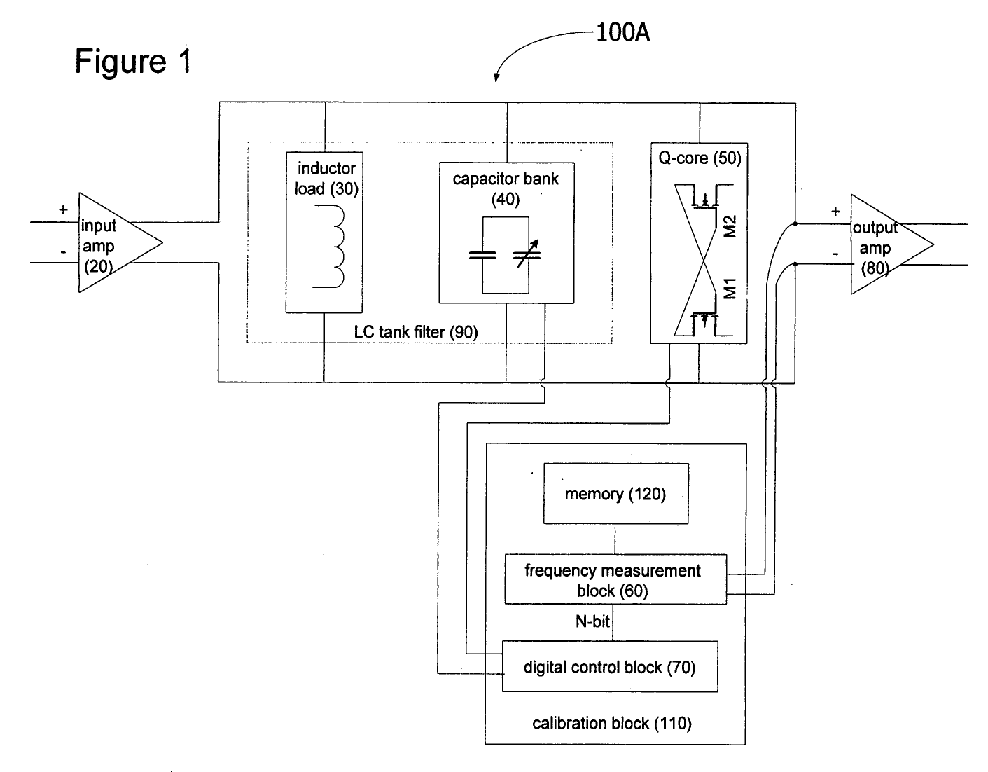

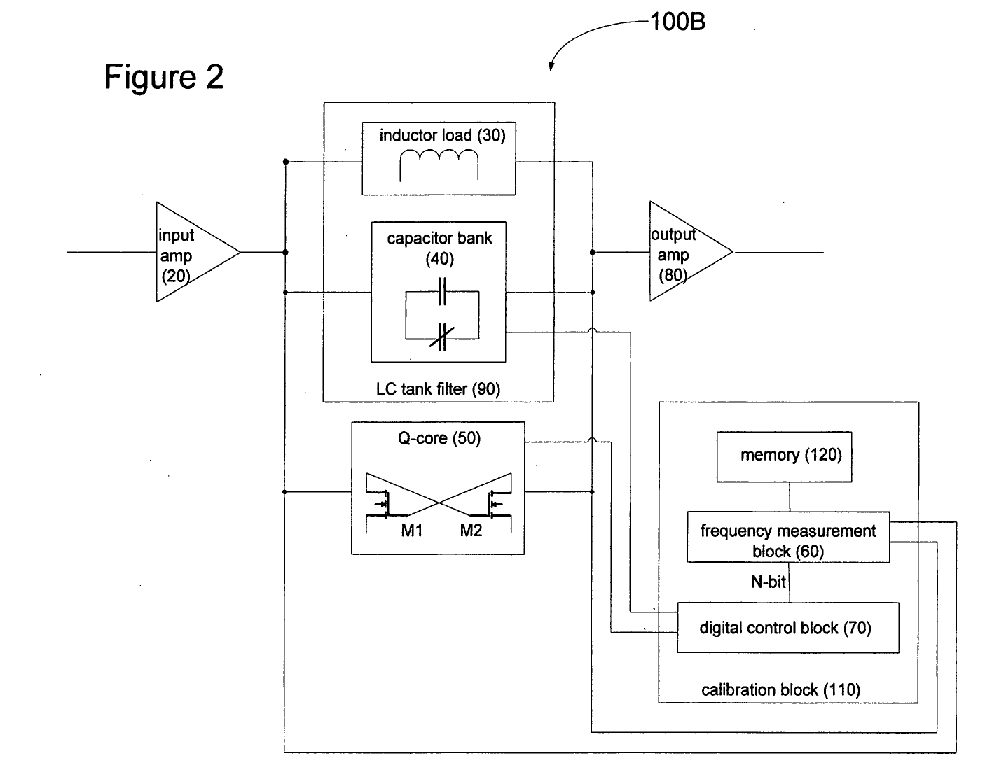

FIGS. 1 and 2 are schematic block diagrams of enhanced filtering systems 100A and 100B, respectively, according to some embodiments. FIG. 1 features a band-pass filter 100A and FIG. 2 features a band-stop filter 100B. Any one of these circuit arrangements, as well as other LC circuits not explicitly described herein, may implement the enhanced filtering methods described below. For simplicity, the filter systems of FIGS. 1 and 2 are referred to herein as simply, “enhanced filtering system 100”.

The enhanced filtering system 100 includes an LC tank filter 90, a Q-enhancement core, or Q-core 50, and a calibration block 110, connected to differential signals between an input amplifier 20 and an output amplifier 80. (A single-ended configuration of the system 100 is also possible.) Instead of the output amplifier 80, the input amplifier may be connected to an antenna or other output. The LC tank filter 90, a tuned-load amplifier, includes an inductor load 30 disposed in parallel with a capacitor bank 40. In some embodiments, the bandwidth of the filtering system 100 is narrow. Thus, the capacitor bank 40 may be adjusted digitally to control the on/off state of the embedded capacitors, which tunes the center frequency of the filter 90. In some embodiments, the digital control of the capacitor bank 40 controls switches which connect and disconnect the embedded capacitors. As one example, the capacitor bank 40 may include a large capacitor, to get the filter into the vicinity of the desired center bandwidth, and several small capacitors, used to tune to the exact frequency. In some embodiments, the capacitor bank 40 is a continuously variable voltage-controlled capacitor, such as a varactor. In other embodiments, the capacitor bank 40 is a continuously variable mechanically controlled capacitor, such as a plate capacitor. System designers of ordinary skill in the art recognize a number of different implementations of the capacitor bank 40 that may be operable in the enhanced filtering system 100.

The Q-core 50 is a negative resistance device used to improve the quality of the filter 90, and includes active components, such as the transistors depicted in FIG. 1. The quality of a filter or “Q-factor”, used to rate the filter, is the ratio between the frequency of the filter and its bandwidth, also known as the relative bandwidth of the filter. The higher the Q of the filter, the higher its quality and the narrower the filter in absolute terms, relative to its center frequency. The active components in the Q-core 50 are adjusted to modify the Q of the LC tank filter 90. Like the capacitor bank 40, the Q-core 50 may be digitally controlled to adjust the current delivered to the filter 90, or to modify the size of transistors within the Q-core, in other words, controlling the amount of Q-enhancement. The components of the Q-core 50 may vary considerably from one design to the next, as is understood by those of ordinary skill in the art.

As a negative resistance, active component device, the Q-core 50 causes oscillations in the filter 90 when facing a positive but larger resistance. Such oscillations, left unchecked, will negate the usefulness of the filter. The enhanced filtering system 100 avoids this problem by including an on-system calibration block 110 to monitor the oscillations and adjust the Q-core to both eliminate the oscillations and maximize the quality of the filter output. The calibration block 110 consists of a frequency measurement block 60 and a digital control block 70. By having the calibration block 110, the oscillatory mode of the system 100 is a legal state that may be controlled to optimize the Q of the filter 90. In some embodiments, the calibration block 110 controls the amount of negative resistance by adjusting the current flowing through the active devices contained in the Q-core 50. In other embodiments, the calibration block 110 controls the amount of negative resistance by switching active devices within the Q-core 50 into or out of the circuit. In still other embodiments, the calibration block 110 controls the amount of negative resistance by implementing an impedance-transforming network between the Q-core 50 and the rest of the filter 90, as well as by varying the transformation ratio. Filter designers of ordinary skill will recognize a number of different design scenarios that may operate within the enhanced filtering system 100.

The enhanced filtering system 100 supports different implementations of the Q-enhancement core 50. In some embodiments, the Q-core 50 includes a cross-coupled transistor pair within a differential circuit, or a parallel tank within a single-ended circuit. In some embodiments, the Q-core 50 includes a Colpitts negative-resistance cell within a differential or single-ended circuit. In some embodiments, the Q-core 50 is implemented as a coupled-inductor to negative resistance cell within a differential or single-ended circuit.

The enhanced filtering system 100 improves the filtering performance attainable from on-chip devices compared to prior art designs, by enabling the use of in-system Q-enhancement (the Q-core 50) and calibration (the calibration block 110). With prior art designs, the filtering performance is poor due to the low Q of the on-chip inductors and capacitors. The process variation (mainly due to capacitor and inductor variation) requires calibration of the tuned load. Without calibration, the bandwidth may be further increased (by further lowering Q), but this all but eliminates any filtering benefits the Q-enhancement block may have provided. The enhanced filtering system 100 functions for all process corners (manufacturing variations) and operating conditions by automatically addressing oscillations within the system.

The Q-core 50 introduces an effective negative resistor in parallel with the LC tank filter 90, thus increasing the effective Q of the filter and lowering the bandwidth. However, when the negative resistance is small enough (smaller in absolute value than the effective parallel resistance of the LC tank 90), oscillations will occur. Because of these two properties, in some embodiments, both the center frequency of the filter 90 and the amount of negative resistance (Q-enhancement) are precisely controlled, in order to use the enhanced filtering system 100 effectively.

The enhanced filtering system 100 uses the inherent property of self-induced oscillations to calibrate the filter 90. In some embodiments, oscillations occur at almost exactly the center frequency of the filter 90, since this is the frequency of least resistance (known as the tuned-tank frequency). By measuring the oscillation frequency of the filter 90 while it is in an oscillatory mode (at a given setting of the capacitor bank 40), the operating frequency range the given state of the filter will support may be known. This is achieved without any extra circuitry or signal paths, thus reducing the complexity and size of the solution. In addition, by accurately controlling the amount of Q-enhancement (by digitally controlling the current or device sizes in the Q-core 50), the setting in which the oscillations start and stop may be found, thus determining the amount of negative resistance to achieve a given bandwidth.

The LC tank filter 90 in FIG. 1 represents one of several configurations that may be implemented in the enhanced filtering system 100. In some embodiments, the LC tank 90 is in a parallel configuration, in which the two terminals of the capacitor bank 40 and the inductor load 30 are connected to each other, with both being used interface with the rest of the circuit. In other embodiments, the LC tank filter 90 is in a serial configuration, where the capacitor bank 40 and the inductor load 30 are connected to each other at one terminal, with the other terminal of each being used to interface with the rest of the circuit. In some embodiments, the LC tank filter 90 uses a differential signal path, where a “positive” path and a “negative” path are routed in parallel, each carrying the inverse of the signal on the other. In other embodiments, the LC tank filter 90 uses a single-ended path, where a single path is used for the signal, referenced to a common “ground” or zero-voltage reference. In some embodiments, the LC tank filter 90 is configured as a band-pass filter, by connecting a shunt parallel tank or an in-line series tank. In other embodiments, the LC tank filter 90 is configured as a band-stop (“notch”) filter, by connecting a shunt series tank or an in-line parallel tank. Filter designers of ordinary skill recognize a variety of configurations that may be supported by the enhanced filtering system 100.

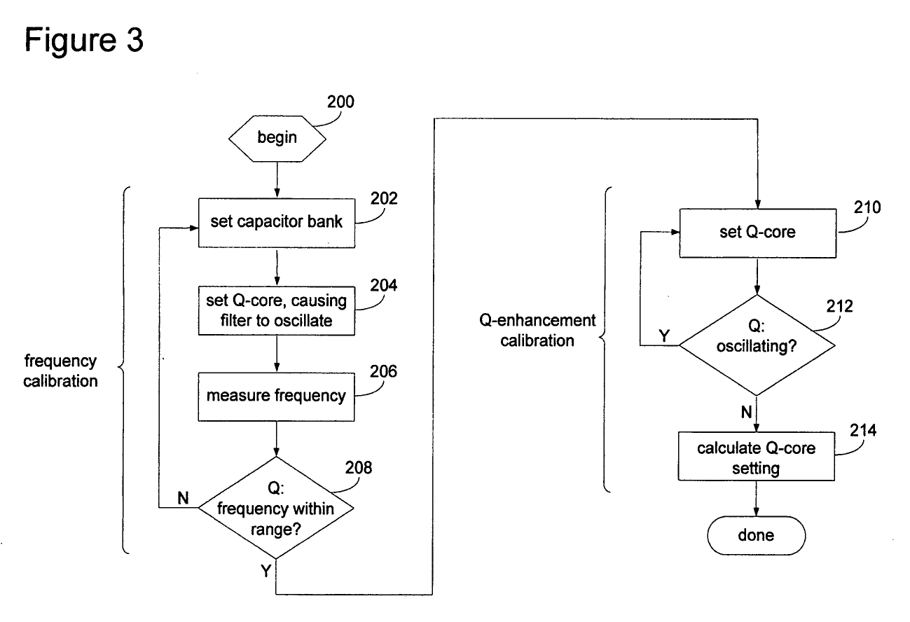

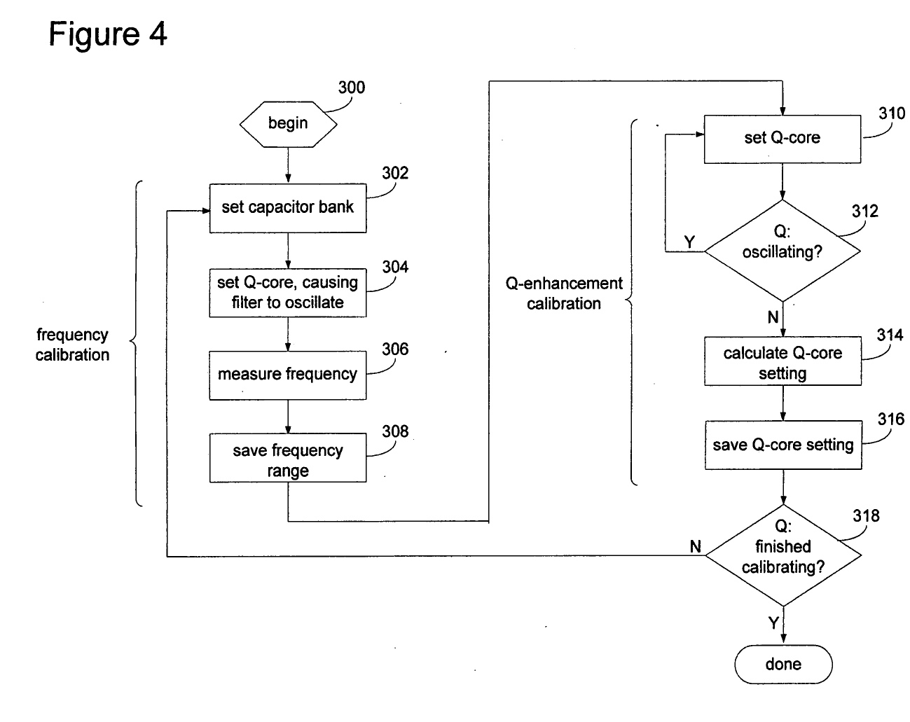

Flow charts showing operation of the calibration block 110 of the enhanced filtering system 100 are presented in FIGS. 3 and 4, according to some embodiments. Both options for the filter calibrations similarly use filter properties in order to find the optimal setting of the Q-core 50. Whether searching for the optimal setting for a given frequency, or recording a table of the operating frequencies of each capacitor bank 40 setting, many of the same steps are used in each flow diagram. These procedures rely on the circuit design, ensuring that both oscillatory and stable operations are available at all manufacturing variations and operating conditions.

In FIG. 3, the process flow 200 of the enhanced filtering system 100 begins by setting the capacitor bank 40 to tune the center frequency of the LC tank filter 90 (block 202). The capacitor bank 40 may be controlled digitally to switch one or more capacitors on or off, so that the filter 90 filters near a desired center frequency. The Q-core 50 is also set to some desired Q-enhancement, causing the filter 90 to oscillate (block 204). During oscillation, the center frequency of the LC tank filter 90 is measured (block 206). If the frequency is not within range of the desired center frequency, as measured by the frequency measurement block 60, steps 202, 204, and 206 are repeated (block 208), with the capacitor bank 40 receiving a different setting, followed by the Q-core 50 being set. In some embodiments, both the capacitor bank 40 and Q-core 50 settings are controlled by the digital control block 70 in the calibration block 110.

If, however, the frequency is within range of the desired center frequency, the frequency calibration is complete, and the capacitor bank 40 is not further modified. Next, the Q-core 50 is again adjusted (block 210) until the filter 90 stops oscillating (block 212). For example, a high Q may be selected initially, followed by lower and lower Q values, until the oscillation stops. Once a first non-oscillating mode occurs, calculation from that transition point occurs, and the final Q-core setting is calculated (block 214).

In FIG. 4, the process flow 300 further describes a preliminary calibration to cover a large set of possible operating conditions, such as several supported frequencies, in some embodiments. After the capacitor bank 40 (block 304) and Q-core 50 (block 50) are set, the center frequency is measured (block 306), as in the flow diagram 200. This time, the center frequency is saved, as part of a saved frequency range of the filter 90 (block 308). In some embodiments, the calibration block 110 includes a memory 120 for this purpose. Until the calibration is finished, the steps of the process flow 300 may be repeated several times. Thus, the saved center frequencies provide a range of supported frequencies.

For the last saved center frequency, the Q-core 50 is repeatedly set (block 310) until the oscillation stops (block 312). The Q-core setting is then calculated (block 314) and saved (block 316). Where the calibration is not complete (block 318), the process is repeated. In some embodiments, the calibration is considered not complete where there are other center frequencies or other settings yet to be calibrated for and stored in the memory 120. Otherwise, the operations are complete.

Calibrating a filter using an oscillator at the same frequency is not new, but is mainly used for base-band filters at much lower frequencies, and most often for low-pass (as opposed to band-pass) filters. These filters are calibrated either by replicating core pieces of the filter and connecting them in a different manner so as to create an oscillator, or by creating an extra signal path (e.g., from the filter output to its input), which causes the filter to oscillate. The enhanced filtering system 100 is novel in the use of the same filter circuits, without replicating or reconnecting anything, to create the oscillator. This is made possible by the unique behavior of the negative-resistance Q-enhancement core.

The enhanced filtering system 100 may be used in a multiple-input-multiple-output (MIMO) communications environment. More generally, the enhanced filtering system 100 may be used in a system where a digital circuit is used in order to calibrate RF/analog circuits to bring them to the specified performance levels. The enhanced filtering system 100 may be used in platforms where there is an integration of more than one communications module (e.g., multi-mode handheld devices, laptops, etc.)

The enhanced filtering system 100 is operable without external filtering, which may lower the overall price and the total footprint (required board area) of a product, with only a small increase in power consumption. If the external filter is completely eliminated from the product, the overall power consumption may even be decreased, due to the reduced losses in the chain (at points much more sensitive to such losses).

While the application has been described with respect to a limited number of embodiments, those skilled in the art will appreciate numerous modifications and variations therefrom. It is intended that the appended claims cover all such modifications and variations as fall within the true spirit and scope of the invention.

We claim:

1. A system, comprising:
a filter coupled to an input amplifier, the filter to filter signals around a center frequency, wherein the center frequency is adjustable;
a Q-core comprising a negative resistance, the Q-core to increase an adjustable quality, Q, of the filter, wherein the Q-core causes the filter to oscillate when being loaded by a positive resistance whose absolute value is larger than the negative resistance; and
a calibration block to adjust the center frequency or the Q; wherein the calibration block is arranged to set the center frequency, sets or resets Q, and repeatedly modifies Q, if necessary, until oscillation of the filter stops.

2. The system of claim 1, the band-pass filter further comprising:
an inductor load; and
an adjustable capacitor;
wherein the adjustable capacitor is digitally adjustable by the calibration block to change the center frequency around which filtration occurs.

3. The system of claim 2, the Q-core further comprising:
a plurality of transistors, wherein the transistors are digitally adjustable by the calibration block to modify the negative resistance of the Q-core.

4. The system of claim 2, the calibration block further comprising:
a digital control block to adjust the number of capacitors in the capacitor bank that are switched on, wherein the adjustment changes the center frequency.

5. The system of claim 3, the calibration block further comprising:
a digital control block to adjust the number of transistors in the plurality of transistors that are switched on, wherein the adjustment changes the negative resistance of the Q-core.

6. The system of claim 4, the calibration block further comprising:
a frequency measurement block to measure the center frequency.

7. The system of claim 6, the calibration block further comprising:
a memory to store the measured center frequency, wherein the memory is further used to save the Q of the filter and the number of capacitors.

8. The system of claim 1, wherein the filter is a band-pass filter.

9. The system of claim 1, wherein the filter is a band-stop filter.

10. A method, comprising:
adjusting a capacitor bank of a band-pass filter, wherein the adjustment controls a center frequency around which the band-pass filter operates;
adjusting a Q-core comprising a negative resistance, the adjustment changing the negative resistance, wherein the adjustment causes the filter to oscillate; and
continuing to adjust the Q-core until the filter no longer oscillates.

11. The method of claim 10, further comprising:
measuring the center frequency; and
further adjusting the capacitor bank when the center frequency is not within a predetermined range.

12. The method of claim 11, adjusting a capacitor bank further comprising:
switching one or more capacitors of the capacitor bank.

13. The method of claim 10, adjusting a Q-core further comprising:
switching an active component in the Q-core.

14. The method of claim 13, switching an active component in the Q-core further comprising:
switching a transistor in the Q-core.

15. The method of claim 11, further adjusting the capacitor bank when the center frequency is not within a predetermined range further comprising:
repeatedly adjusting the capacitor bank until the center frequency is within the predetermined range before adjusting the Q-core.

16. A method, comprising:
adjusting a capacitor bank of a filter in a system, wherein the adjustment controls a center frequency around which the filter operates;
adjusting a Q-core in the system, the Q-core comprising a negative resistance, the adjustment changing the negative resistance, wherein the adjustment causes the filter to oscillate; and
measuring the center frequency.

17. The method of claim 16, further comprising:
saving the measured center frequency in a memory.

18. The method of claim 17, further comprising:
adjusting a Q-core to change a negative resistance of the Q-core, wherein the adjustment causes the filter to oscillate and further adjustment causes the filter to not oscillate, thereby providing an oscillation threshold for the Q-core; and
calculating the adjusted Q-core setting to obtain a desired amount of Q-enhancement of the system.

19. The method of claim 18, further comprising:
readjusting the capacitor bank if the center frequency is not equal to a predetermined center frequency.

20. The method of claim 18, further comprising:
storing the Q-enhancement in the memory, wherein the range of center frequencies and Q-enhancements are accessible from the memory.
